(19) United States
(12) Patent Application Publication
(10) Pub. No.: US 2007/0139140 A1
(43) Pub. Date: Jun. 21, 2007

(54) Frequency tuning of film bulk acoustic resonators (FBAR)

(76) Inventors: Valluri R. Rao, Saratoga, CA (US); Theodore G. Doros, Sunnyvale, CA (US); Qing Ma, San Jose, CA (US); Krishna Seshan, San Jose, CA (US); Li-Peng Wang, San Jose, CA (US)

Correspondence Address: INTEL CORPORATION;c/o INTELLEVATE, LLC, P.O. BOX 52050, MINNEAPOLIS, MN, 55402, US

(21) Appl. No.: 11/314,361

(22) Filed: Dec. 20, 2005

(51) Int. Cl. H03H 9/58

(52) U.S. Cl. 333/188

(57) ABSTRACT

Multiple FBARs may be manufactured on a single wafer and later diced. Ideally, all devices formed in a wafer would have the same resonance frequency. However, due to manufacturing variances, the frequency response of the FBAR devices may vary slightly across the wafer. An RF map may be created to determine zones over the wafer where FBARs in that zone all vary from a target frequency by a similar degree. A tuning layer may be deposited over the wafer. Lithographically patterned features to the tuning layer based on the zones identified by the RF map may be used to correct the FBARs to a target resonance frequency with the FBARs still intact on the wafer.

### FIELD OF THE INVENTION

Embodiments of the present invention relate to film bulk acoustic resonators (FBARs) and, more particularly to frequency tuning on a wafer level scale.

### BACKGROUND INFORMATION

In wireless radio frequency (RF) devices, resonators are generally used for signal filtering and generation purposes. The current state of the art typically is the use of discrete crystals to make the resonators. To miniaturize devices, micro-electromechanical systems (MEMS) resonators have been contemplated. One type of MEMS resonator is a film bulk acoustic resonator (FBAR). A FBAR device has many advantages over prior art resonators such as low insertion loss at high frequencies and small form factor.

In addition to resonators, film bulk acoustic resonator (FBAR) technology may be used as a basis for forming many of the frequency components in modern wireless systems. For example, FBAR technology may be used to form filter devices, oscillators, resonators, and a host of other frequency related components. FBAR may have advantages compared to other resonator technologies, such as Surface Acoustic Wave (SAW) and traditional crystal oscillator technologies. In particular, unlike crystals oscillators, FBAR devices may be integrated on a chip and typically have better power handling characteristics than SAW devices.

The descriptive name given to the technology, FBAR, may be useful to describe its general principals. In short, “Film” refers to a thin piezoelectric film such as Aluminum Nitride (AlN) sandwiched between two electrodes. Piezoelectric films have the property of mechanically vibrating in the presence of an electric field as well as producing electrical charges if mechanically vibrated. “Bulk” refers to the body or thickness of the sandwich. When an alternating voltage is applied across the electrodes the film begins to vibrate. “Acoustic” refers to this mechanical vibration that resonates within the “bulk” (as opposed to just the surface in a SAW device) of the device.

The resonance frequency of a FBAR device is determined by its thickness, which must be precisely controlled in order to have the desired filter response, such as exact central frequency and pass bandwidth. In a typical (FBAR) device, the resonance frequency after processing is usually different from the targeted value due to processing variation. For discrete crystal resonators as mentioned above, such resonance frequency error may be corrected using laser trimming technology, for example, in which a laser is directed towards the resonator and either removes or adds material to the resonator, thereby “tuning” the resonating frequency of the resonator to the desired targeted frequency. However, because MEMS resonators (particularly high frequency MEMS resonators) are generally much smaller in size than their crystal counterparts, traditional laser trimming technology is not a viable alternative. Accordingly, what is needed are techniques to modify the resonance frequency of a MEMS resonator.

### BRIEF DESCRIPTION OF THE DRAWINGS

FIG. 1 is a cross-sectional view of a film bulk acoustic resonator (FBAR);

FIG. 2 is a schematic of an electrical circuit of the film bulk acoustic resonator (FBAR) shown in FIG. 1;

FIG. 3 is a block diagram of an FBAR according to one embodiment of the invention;

FIG. 4 is a block diagram of an FBAR according to one embodiment of the invention;

FIG. 5 is a wafer frequency map according to an embodiment of the invention;

FIG. 6 is a wafer zone map identifying various zones to be tuned by various degrees;

FIG. 7 is an FBAR having a percentage of the tuning layer removed to tune its resonance frequency to a target value;

FIG. 8 is a graph illustrating frequency change of an FBAR verses the percentage of covering of the tuning patterns;

FIG. 9 is a graph showing the lithographic accuracy for the thickness of the tuning layer;

FIG. 10 is a block diagram showing two adjacent FBARs on a wafer tuned to various degrees in neighboring zones; and

FIG. 11 is a flow diagram illustrating the process for tuning FBARs on a wafer according to one embodiment of the invention.

### DETAILED DESCRIPTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

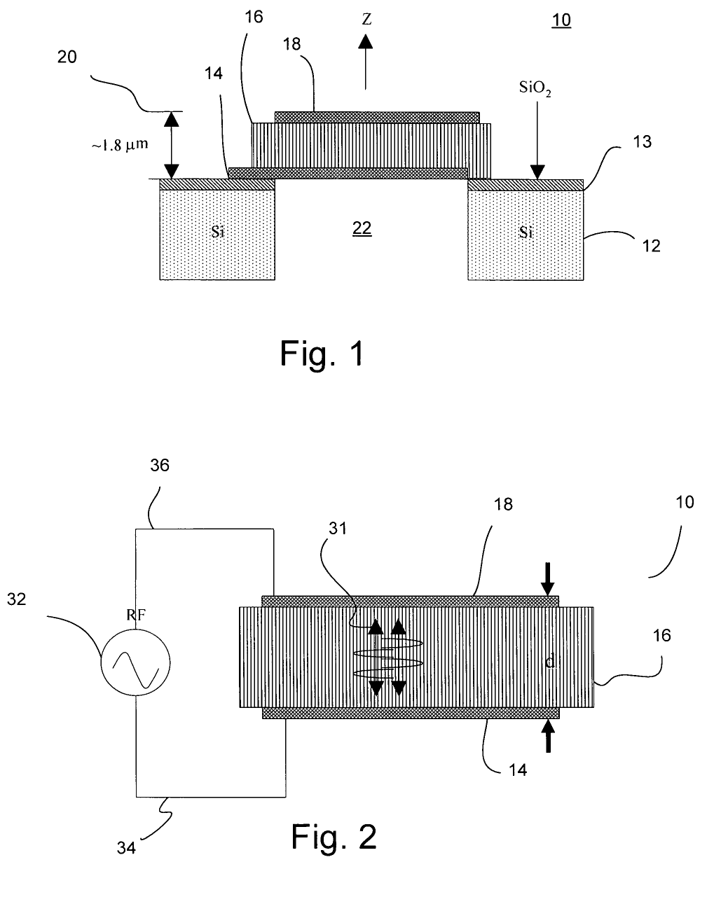

An FBAR device 10 is schematically shown in FIG. 1. The FBAR device 10 may be formed on the horizontal plane of a substrate 12, such as silicon and may include an SiO₂ layer 13. A first layer of metal 14 is placed on the substrate 12, and then a piezoelectric layer 16 is placed onto the metal layer 14. The piezoelectric layer 16 may be Zinc Oxide (ZnO), Aluminum Nitride (AlN), Lead Zirconate Titanate (PZT), or any other piezoelectric material. A second layer of metal 18 is placed over the piezoelectric layer 14. The first metal layer 14 serves as a first electrode 14 and the second metal layer 18 serves as a second electrode 18. The first electrode 14, the piezoelectric layer 16, and the second electrode 18 form a stack 20. As shown, the stack may be, for example, around 1.8 μm thick. A portion of the substrate 12 behind or beneath the stack 20 may be removed using back side bulk silicon etching to form an opening 22. The back side bulk silicon etching may be done using deep trench reactive ion etching or using a crystallographic-orientation-dependent etch, such as Potassium Hydroxide (KOH), Tetra-Methyl Ammonium Hydroxide (TMAH), and Ethylene-Diamene Pyrocatechol (EDP).

The resulting structure is a horizontally positioned piezoelectric layer 16 sandwiched between the first electrode 14 and the second electrode 16 positioned above the opening 22 in the substrate 12. In short, the FBAR 10 comprises a membrane device suspended over an opening 22 in a horizontal substrate 12.

FIG. 2 illustrates the schematic of an electrical circuit 30 which includes a film bulk acoustic resonator 10. The electrical circuit 30 includes a source of radio frequency “RF” voltage 32. The source of RF voltage 32 is attached to the first electrode 14 via electrical path 34 and attached to the second electrode 18 by the second electrical path 36. The entire stack 20 can freely resonate in the Z direction 31 when an RF voltage 32 at resonant frequency is applied. The resonant frequency is determined by the thickness of the membrane or the effective thickness of the piezoelectric film stack which is designated by the letter “d” or dimension “d” in FIG. 2. The resonant frequency is determined by the following formula:

f0≈V/2d, where

f0=the resonant frequency,

V=acoustic velocity of piezoelectric layer, and

d=the thickness of the piezoelectric film stack.

It should be noted that the structure described in FIGS. 1 and 2 can be used either as a resonator or as a filter. To form an FBAR, piezoelectric films 16, such as ZnO, PZT and AlN, may be used as the active materials. The material properties of these films, such as the longitudinal piezoelectric coefficient and acoustic loss coefficient, are parameters for the resonator's performance. Performance factors include Q-factors, insertion loss, and the electrical/mechanical coupling. To manufacture an FBAR the piezoelectric film 16 may be deposited on a metal electrode 14 using for example reactive sputtering. The resulting films are polycrystalline with a c-axis texture orientation. In other words, the c-axis is perpendicular to the substrate.

Multiple FBARs may be manufactured on a single wafer and later diced. Ideally, all devices formed in a wafer would have the same resonance frequency. However, due to manufacturing variances, the frequency response of the FBAR devices may vary slightly across the wafer. The fundamental resonant frequency of an FBAR is mainly determined by the thickness of piezoelectric film stack, which approximately equals the half wavelength of the acoustic waves. The frequencies of the FBARs should be precisely set in order to achieve the desired filter response, such as the center frequency and pass bandwidth. For example, the bandpass filter used in mobile phone applications, the frequency control is required to be within 4 MHz at 2 GHz range, which is within ˜0.2% of the frequency variation. Such accuracy is difficult to achieve by any state-of-the-art deposition tool. Therefore, an effective and low-cost post-processing technology is used for manufacturing FBAR devices.

After dicing, the individual FBAR devices may be fine tuned individually. Currently, a post-processing of ion beam trimming is usually used to correct the frequency by ion milling top electrodes. Additional ion beam equipment and maintenance are required. The throughput is also low because of its series processes (trimming from die to die). Therefore, ion beam trimming technique is not cost effective. Therefore, tuning all FBAR devices in parallel while still on the wafer would be preferred.

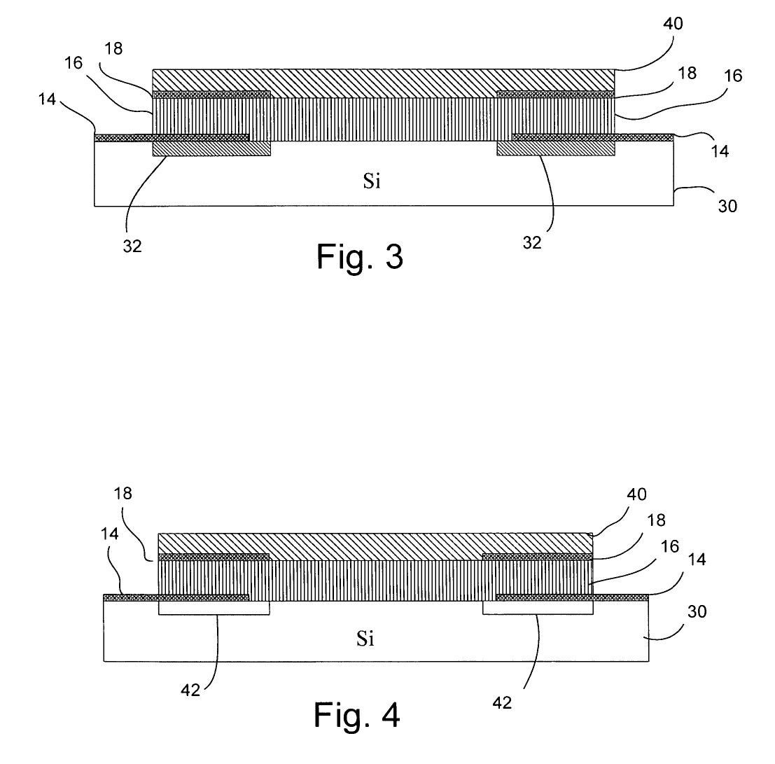

FIG. 3 shows two adjacent FBAR devices formed in a wafer. A sacrificial release layer 32, for example, SiO₂, may be patterned on a silicon substrate 30. A bottom electrode layer 34 may then be deposited over the substrate 30 partially over the release layer 32. The bottom electrode may be, for example, Al, Mo, Pt, or W. A piezoelectric layer 36, such as, AlN, PZT, or ZnO, may then be deposited over the bottom electrode 14. A top electrode, for example Al, Mo, Pt, or W, may then be patterned over the piezoelectric layer 38. According to embodiments of the invention, a tuning layer 40 may then be deposited over the top electrode layer 38. The tuning layer may be any high-Q metal, such as, for example AlN. Thereafter, as shown in FIG. 4, the sacrificial SiO₂ layer is removed, such as by etching, thereby creating the openings 42.

According to embodiments of the invention, by adding lithographically patterned features to the tuning layer 40 on top of the FBAR membranes the resonance frequencies of FBARs may be tuned by controlling the dimension and shape of the pattern features. In addition, the lithographical features can be varied by controlling the lithographic exposure dose. Combining these two, it provides the capability to correct the resonator frequency in an effective and low-cost way with the FBARs still intact on the wafer.

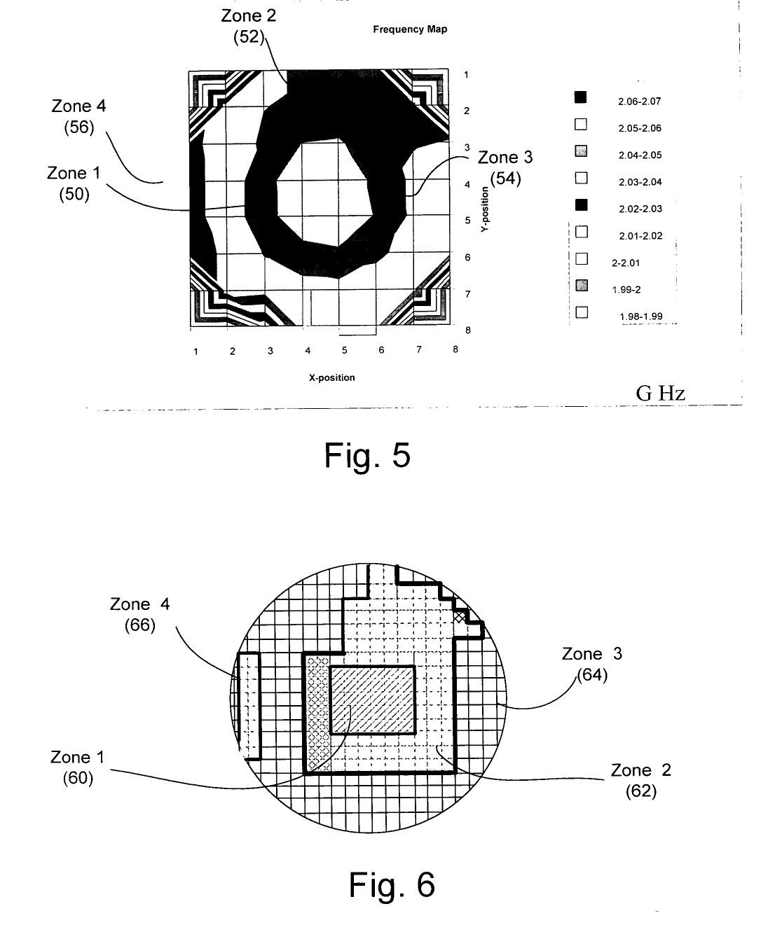

FIG. 5 shows a wafer frequency map measured by RF testing. As shown, the resonance frequency of the individual FBARs varies slightly in different zones across the wafer. For simplicity of illustration, four main zones are identified. The FBARs in zone 1 (50) have a resonance frequency of 2.03-2.04 GHz. The FBARs in zone 2 (52) have a resonance frequency of 2.04-2.05 GHz. The FBARs in zone 3 (54) have a resonance frequency of 2.05-2.06 GHz. Finally, the FBARs in zone 4 (56) have a resonance frequency of 1.99-2.00 GHz according to the wafer frequency map. Four zones are identified across the wafer, however, in theory the granularity of the zones may be more precise right down to the individual die level.

As shown in FIG. 6, from the wafer frequency map, a correction map (the requirement of frequency change for each die or die within a zone) may be obtained. For example, the correction map may similarly comprise four zones, zone 1 (60), zone 2 (62), zone 3 (64) and zone 4 (66) corresponding to the zones identified in FIG. 5. Different lithographic patterns, corresponding to the correction map, may be achieved by changing the lithographic exposure dose for die within a zone. Resonance frequencies of FBARs in the zones may be corrected to the targeted value with these lithographically defined patterns. That is, in each zone a different amount of or pattern of the tuning layer 40 may be removed. For example, in Zone 1, 30% of the tuning layer 40 may be removed. In Zone 2, 40% of the tuning layer may be removed and so forth. Thus, fine tuning the FBARs in each zone may be achieved such that the resonance frequencies of all the FBARs on the wafer may be substantially the same.

In practice, it may not be necessary to create a new wafer frequency map and correction map as shown in FIGS. 5 and 6 for each wafer. Rather, the frequency map may be similar for a batch of wafers coming off the line. Thus, for example, if the wafers are manufactured in batches of say twenty wafers, one frequency map and correction map may suffice for the entire batch.

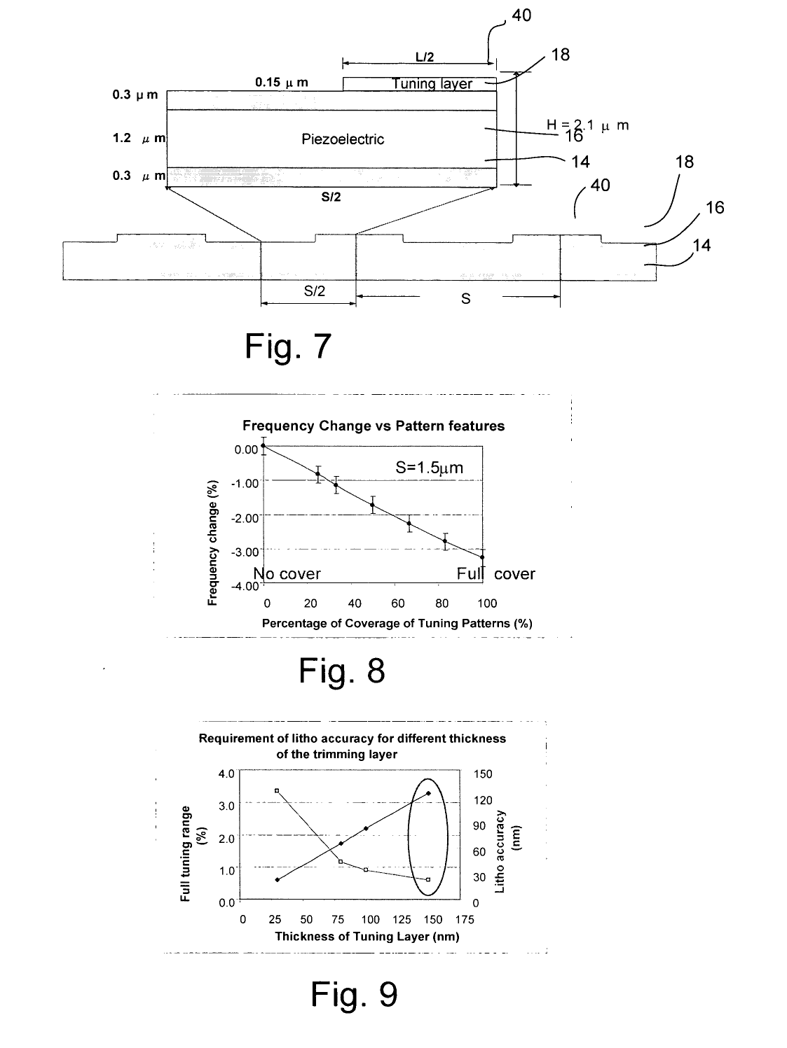

Referring now to FIG. 7 there is shown an FBAR showing the bottom electrode 14, the piezoelectric layer 16, and the top electrode 18. Here, the tuning layer 40 has been etched on the top electrode 18 in the form of periodic straight lines (perpendicular to the paper) according to one embodiment if the invention. While etched straight lines are shown for simulation calculations, other patterns may be possible. For illustrative purposes the bottom electrode 14 has a thickness of 0.3 μm, the piezoelectric layer 16 a thickness of 1.2 μm, the top electrode 18 a thickness of 0.3 μm and the tuning layer 40 a thickness of 0.15 μm. Thus, the entire height (H) of the stack, including the tuning layer, is about H=2.1 μm. The period between the etched lines of the tuning layer 40 is labeled as “S” and the length of each of the lines is labeled as “L”.

FIG. 8 depicts a simulation graph showing the frequency change of the FBAR varying by the percentage of cover of the tuning pattern 40 remaining on the top electrode 18 when the period of the tuning pattern is approximately S=1.5 μm. As shown, when 0% (no cover) of the tuning layer remains to 100% (full cover) of the tuning layer remains, the frequency of the FBAR may be tuned anywhere within a 4.00% frequency change. Pattern features of the tuning layer 40 should be smaller than characteristic dimension in order to remain single peak (pure mass loading effect). In this case, the pattern period (S) should be smaller than 1.5 μm for H=2.1 μm to remain a single peak where L may vary from 0-1.5 μm.

As shown in FIG. 9, the requirement of lithographic accuracy increases with increasing thickness of the tuning layer 40. Thus, lithographic accuracy of about 23 nm is used to have a tuning range of about 3.27%. This accuracy may be achieved by current lithographical tools.

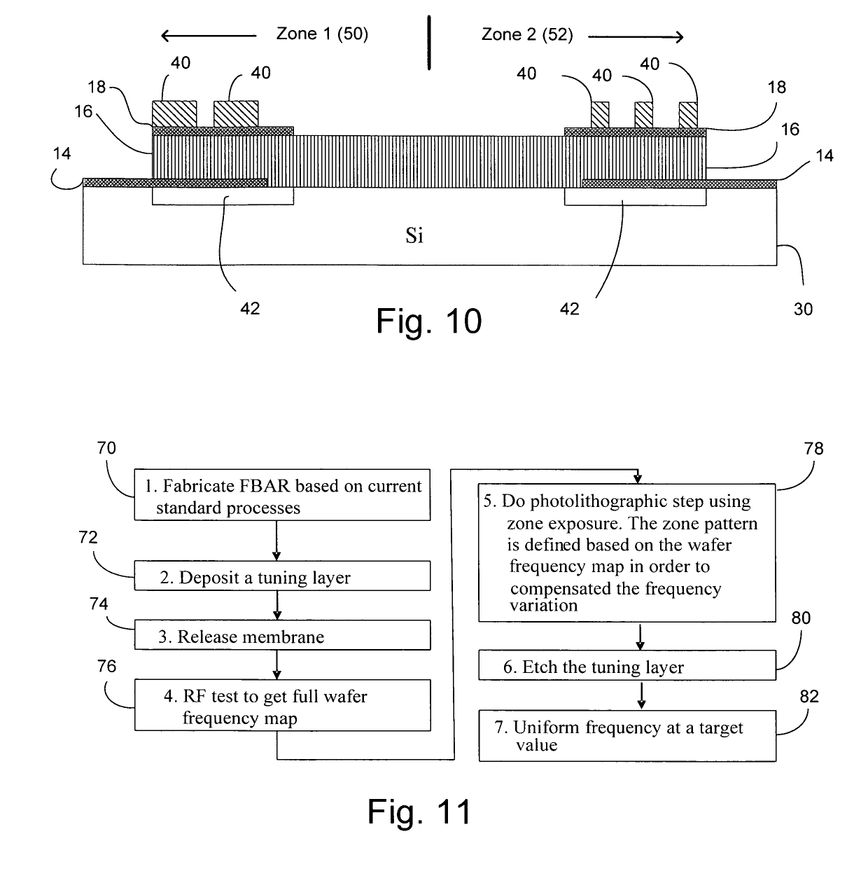

FIG. 10 is an example of two tuned FBARs on a wafer. The example is similar to that shown in FIG. 4. Like reference numerals are used to refer to like items and not again described to avoid repetition. As illustrated, two FBARs on a wafer are shown bordering, for example zones 1 and 2. The FBAR in Zone 2 has a larger percentage of its tuning layer 40 removed than the FBAR in Zone 2. Thus, the resonant frequencies for all of the FBARs on the wafer may be corrected to a target value prior to dicing.

FIG. 11 shows a flow diagram outlining the procedures according to one embodiment of the invention. In block 70 the FBARs are fabricated on a wafer using standard processes. In block 72, the tuning layer 40 is placed over the upper electrode 18. The release membrane is then removed in block 74 leaving openings 42 as shown for example in FIG. 10. At block 76 an RF test is conducted to obtain a full wafer frequency map as illustrated in FIG. 5. In block 78 a photolithographic process using zone exposure is performed over the tuning layer 40.

The zone pattern as shown in FIG. 6 is based on the wafer frequency map in order to compensate for frequency variation of the FBARs across the wafer. In block 82 the tuning layer is etched to remove varying percentages of the tuning layer 40 from the various zones as shown in FIG. 10. In block 82, all the FBARs on the wafer may now have a uniform resonance frequency at a selected target value.

The above description of illustrated embodiments of the invention, including what is described in the Abstract, is not intended to be exhaustive or to limit the invention to the precise forms disclosed. While specific embodiments of, and examples for, the invention are described herein for illustrative purposes, various equivalent modifications are possible within the scope of the invention, as those skilled in the relevant art will recognize.

These modifications can be made to the invention in light of the above detailed description. The terms used in the following claims should not be construed to limit the invention to the specific embodiments disclosed in the specification and the claims. Rather, the scope of the invention is to be determined entirely by the following claims, which are to be construed in accordance with established doctrines of claim interpretation.

What is claimed is:

1. An apparatus, comprising:
a wafer;
a plurality of devices each having a resonant frequency associated therewith fabricated on the wafer;
a tuning layer atop the plurality of devices;
a plurality of zones associated with the tuning layer wherein various zones comprise different tuning layer pattern features to tune the plurality of devices to a target resonance frequency.

2. The apparatus as recited in claim 1 wherein the plurality of devices comprise micro-electromechanical systems (MEMS) devices.

3. The apparatus as recited in claim 2 wherein the MEMS devices comprise film bulk acoustic resonators (FBARs).

4. The apparatus as recited in claim 3 wherein the pattern features comprise periodic straight lines.

5. The apparatus as recited in claim 1 wherein the tuning layer comprises a high-Q metal.

6. The apparatus as recited in claim 4 wherein the periodic straight lines comprise a percentage of the tuning layer in a given zone.

7. The apparatus as recited in claim 6 wherein the percentage of tuning layer ranges from 0% to 100%.

8. A method, comprising:
fabricating a plurality of devices on a wafer;
depositing a tuning layer over the plurality of devices;
identifying a plurality of zones across the wafer in which the devices have similar resonance frequencies;
creating different patterns within the tuning layer in each of zones to tune the plurality of devices to a target resonance frequency.

9. The method as recited in claim 8 wherein the plurality of devices comprise film bulk acoustic resonators (FBARs).

10. The method as recited in claim 9 wherein the identifying comprises:
creating a radio frequency (RF) map for the wafer identifying ones of the plurality of FBARs having similar resonance frequencies.

11. The method as recited in claim 10 further comprising:
creating a correction map from the RF map comprising the different patterns.

12. The method as recited in claim 11, further comprising:
using the correction map and photolithographic techniques to create the zone patterns; and
etching to remove selected portions of the tuning layer.

13. The method as recited in claim 12 wherein the zone patterns comprise periodic lines.

14. The method as recited in claim 12 wherein the periodic lines comprise a percentage of the tuning layer in a given zone.

15. The method as recited in claim 14 wherein the percentage of tuning layer ranges from 0% to 100%.

16. A method for tuning a plurality of film bulk acoustic resonators (FBARs) on a wafer, comprising:
fabricating a plurality of FBARs on a wafer;
depositing a tuning layer atop the FBARS;
creating a radio frequency (RF) map for the wafer identifying zones on the wafer having FBARs with similar resonance frequencies;
creating a correction map based on the RF map comprising pattern features for the tuning layer;
using photolithographic techniques to create the pattern features in the tuning layer to correct the resonance frequency of the plurality of FBARs to a target frequency.

17. The method as recited in claim 16 wherein the tuning layer comprises a high-Q metal.

18. The method as recited in claim 16 wherein the pattern features comprise period lines being a percentage of the tuning layer in a given zone.

19. The method as recited in claim 18 wherein the percentage of tuning layer ranges from 0% to 100%.

20. The method as recited in claim 19 wherein frequency correction ranges from 0%-4%.
